(19) United States
(12) Patent Application Publication
(10) Pub. No.: US 2015/0147542 A1
(43) Pub. Date: May 28, 2015

(54) RESIN COMPOSITION FOR PRINTED CIRCUIT BOARD AND PRINTED CIRCUIT BOARD COMPRISING THE SAME

(71) Applicant: Samsung Electro-Mechanics Co., Ltd., Suwon (KR)

(72) Inventors: Jin Seok MOON, Suwon (KR); Dae Hui Jo, Suwon (KR); Seong Hyun Yoo, Suwon (KR); Hyun Jun Lee, Suwon (KR); Jin Young Kim, Suwon (KR); Geum Hee Yun, Suwon (KR)

(73) Assignee: Samsung Electro-Mechanics Co., Ltd., Suwon (KR)

(21) Appl. No.: 14/334,956

(22) Filed: Jul. 18, 2014

(30) Foreign Application Priority Data
Nov. 25, 2013 (KR) 10-2013-0143721

(51) Int. Cl. H05K 1/03; C08L 63/00

(52) U.S. Cl. CPC H05K 1/0373; C08L 63/00
USPC 428/209; 523/451; 428/418

(57) ABSTRACT

A resin composition for a printed circuit board and a printed circuit board formed of the same. The resin composition for a printed circuit board may have: a liquid crystal oligomer including a structural unit of the Chemical Formula 1 and a structural unit of the Chemical Formula 2 and including a functional group of the Chemical Formula E on at least one end; and an ether-type naphthalene-based epoxy resin of Chemical Formula N. According to an exemplary embodiment, even though a printed circuit board becomes light, thin, and miniaturized, electric, thermal, and mechanical stability of the printed circuit board may be secured.

### CROSS-REFERENCE TO RELATED APPLICATION

This application claims the benefit of Korean Patent Application No. 10-2013-0143721 filed on Nov. 25, 2013, with the Korean Intellectual Property Office, the disclosure of which is incorporated herein by reference.

### BACKGROUND

The present disclosure relates to a resin composition for a printed circuit board and a printed circuit board comprising the same.

A board on which an electronic circuit is printed is used in various electronic products such as computers, semiconductors, displays, communications devices, and the like. Signal lines for transferring signals, insulating layers for preventing short-circuits between the signal lines, or the like, as well as a switching element, or the like, may be formed on the board.

A printed circuit board may be formed by laminating prepreg in which glass cloth is impregnated with an epoxy resin and semi-cured on an inner-layer circuit board including a circuit formed thereon.

Alternatively, the printed circuit board may be formed by a build-up method of alternatively laminating an insulating layer on a circuit pattern of an inner-layer circuit board including a circuit formed thereon to manufacture a board. In the build-up method, via holes are formed by laser processing, or the like, such that signal line density may be increased.

In accordance with the development of electronic devices, such printed circuit boards have gradually been lightened, thinned, and miniaturized, while considerations of electrical, thermal, and mechanical stability in such boards have increased in importance.

In order to realize the densification and thinning of printed circuit boards, the prepreg used in the printed circuit board and a copper clad laminate (CCL) should be manufactured to have reduced insulating thicknesses.

However, as circuit boards have been thinned, the rigidity of the boards themselves has been lowered, such that defects may occur due to a warpage phenomenon at the time of mounting components under high temperature conditions. In order to prevent this phenomenon, a thermosetting polymer resin composition for a board having excellent thermal resistance and thermal expansion properties is required.

### RELATED ART DOCUMENT

(Patent Document 1) Korean Patent Laid-Open Publication No. 2011-0108198

### SUMMARY

An exemplary embodiment in the present disclosure may provide a resin composition for a printed circuit board capable of decreasing a coefficient of thermal expansion (CTE) and increasing a glass transition temperature to improve thermal resistance and durability, and a printed circuit board comprising the same.

According to an exemplary embodiment in the present disclosure, a resin composition for a printed circuit board may contain: a liquid crystal oligomer including a structural unit of the following Chemical Formula 1 and a structural unit of the following Chemical Formula 2 and including a functional group of the following Chemical Formula E on at least one end; and an ether-type naphthalene-based epoxy resin of the following Chemical Formula N:

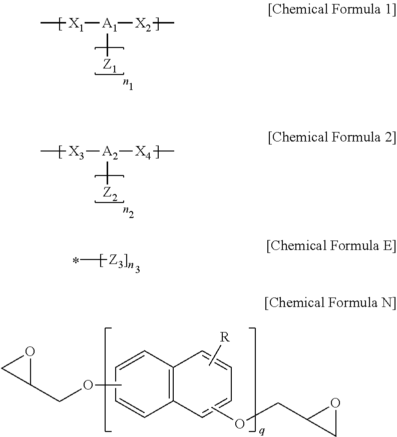

where X₁ to X₄ may each be independently the same as or different to each other and be C(═O)O, O, C(═O)NR, NR′, or CO where R and R′ are each independently the same as or different to each other and are hydrogen, a substituted or unsubstituted (C1-C20) alkyl group or a substituted or unsubstituted (C6-C30) aryl group), Z₁ to Z₃ may each be independently a hydroxyl group; a thiol group; a substituted or unsubstituted maleimide group; a substituted or unsubstituted nadimide group; a substituted or unsubstituted tetrahydrophthalimide group; a substituted or unsubstituted (C2-C30) alkenyl group; a substituted or unsubstituted (C2-C30) alkynyl group; a substituted or unsubstituted propagyl ether group; a substituted or unsubstituted benzocyclobutene group; a (iso)cyanate group; a cyanide group; a substituted or unsubstituted (C3-C30) alicyclic group having a double or triple bond; a substituted or unsubstituted (C3-C30) hetero atom-containing alicyclic group having a double or triple bond; a (C3-C30) alicyclic group including a (C2-C30) alkenyl group or (C2-C30) alkynyl group; a (C3-C30) hetero atom-containing alicyclic group including a (C2-C30) alkenyl group or (C2-C30) alkynyl group; a (C6-C30) aryl group including a (C2-C30) alkenyl group or (C2-C30) alkynyl group; a (C6-C30) aryl group having a (iso)cyanate group or cyanide group; or a combination thereof, n1 to n3 may each be independently integers of 0 to 3, and n1+n2+n3 may be 1 or more, and

A₁ may be one of functional groups represented by the following Chemical Formulas 4-1 to 4-7,

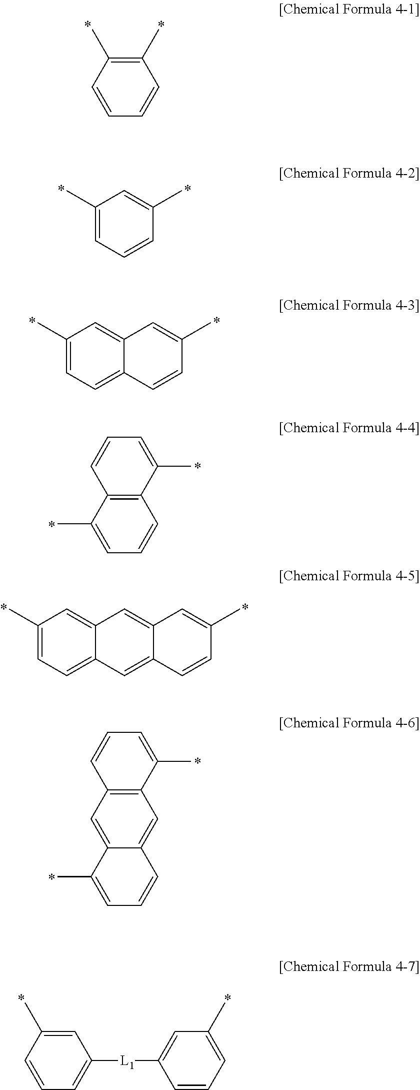

where L₁ is a divalent organic functional group, and in Chemical Formulas 4-1 to 4-7, at least one hydrogen atom of each aromatic ring may be substituted with halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, or Z₁ (Z₁ is the same as in Chemical Formula 1), and

where A₂ may be one of functional groups represented by the following Chemical Formulas 5-1 to 5-6 or a (C2-C20) alkylene group having a functional group of the following Chemical Formula 6,

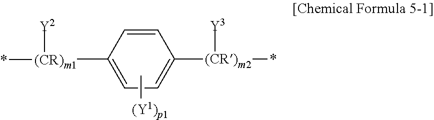

where Y⁴ to Y³ are each independently the same as or different to each other and are each hydrogen, a (C1-C10) alkyl group, or a functional group of the following Chemical Formula 6, at least one of Y⁴ to Y³ being the functional group of the following Chemical Formula 6, p1 is an integer of 0 to 4, m1 and m2 are the same or different and are integers of 0 to 3, p1, m1, and m2 are not simultaneously 0, and R and R′ are hydrogen or a (C1-C10) alkyl group,

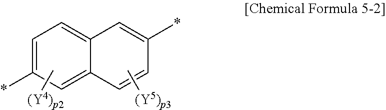

where Y⁴ and Y⁵ are the same as or different to each other and are each hydrogen, a (C1-C10) alkyl group, or a functional group of the following Chemical Formula 6, at least one of Y⁴ and Y⁵ being the functional group of the following Chemical Formula 6, and p2 and p3 are integers of 0 to 3 but are not simultaneously 0,

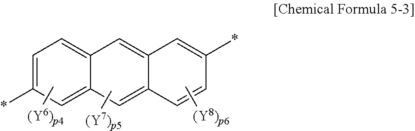

where Y⁶ to Y⁸ are the same as or different to each other and are each hydrogen, a (C1-C10) alkyl group, or a functional group of the following Chemical Formula 6, at least one of Y⁶ to Y⁸ being the functional group of the following Chemical Formula 6, p4 and p6 are integers of 0 to 3, p5 is an integer of 0 to 2, and p4, p5, and p6 are not simultaneously 0,

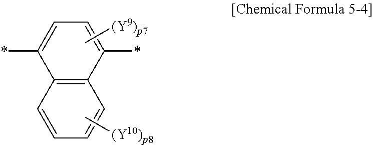

where Y⁹ and Y¹⁰ are the same as or different to each other and are each hydrogen, a (C1-C10) alkyl group, or a functional group of the following Chemical Formula 6, at least one of Y⁹ and Y¹⁰ being the functional group of the following Chemical Formula 6, and p7 and p8 are integers of 0 to 2 but are not simultaneously 0,

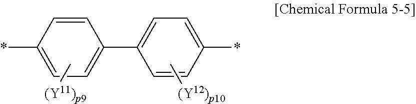

where Y¹¹ and Y¹² are the same as or different to each other and are each hydrogen, a (C1-C10) alkyl group, or a functional group of the following Chemical Formula 6, at least one of Y¹¹ and Y¹² being the functional group of the following Chemical Formula 6, and p9 and p10 are integers of 0 to 4 but are not simultaneously 0,

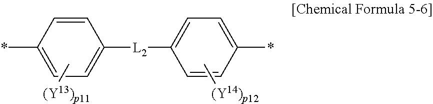

where Y¹³ and Y¹⁴ are the same as or different to each other and are each hydrogen, a (C1-C10) alkyl group, or a functional group of the following Chemical Formula 6, at least one of Y¹³ and Y¹⁴ being the functional group of the following Chemical Formula 6, p11 and p12 are integers of 0 to 4, L₂ is an ether group, a sulfide group, a ketone group, an amide group, a sulfoxide group, a sulfone group, an azo group, a cyanide group, a substituted or unsubstituted (C1-C20) alkylene group, a substituted or unsubstituted (C2-C20) alkenylene group, a substituted or unsubstituted (C6-C30) arylene group, a divalent organic functional group substituted or unsubstituted with at least one functional group of the following Chemical Formula 6, or a divalent organic functional group of the following Chemical Formulas 7-1 to 7-3, and in the case in which L₂ is not substituted with the functional group of the following Chemical Formula 6, one of p11 and p12 is not 0, and in Chemical Formulas 5-1 and 5-6, at least one hydrogen atom of each aromatic ring may be substituted with halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, or Z₁ (Z₁ is the same as in Chemical Formula 1),

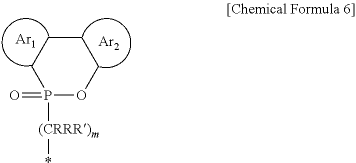

where Ar₁ and Ar₂ are substituted or unsubstituted (C4-C30) aromatic ring groups, R and R′ are the same as or different to each other and are each hydrogen, a (C1-C20) alkyl group, or a (C6-C30) aryl group, and m is an integer of 0 to 3,

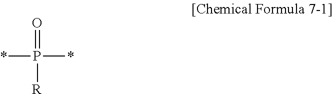

where R is hydrogen, halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, or a substituted or unsubstituted (C6-C30) aryloxy group,

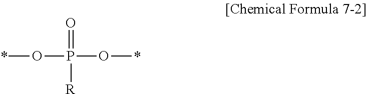

where R is hydrogen, halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, or a substituted or unsubstituted (C6-C30) aryloxy group,

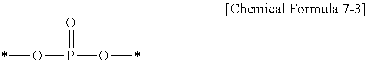

where q is an integer of 2 to 5, and R is each independently hydrogen or one of functional groups represented by the following Chemical Formula 11,

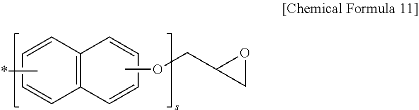

where s is an integer of 1 to 5.

The ether-type naphthalene-based epoxy resin may be contained in a content of 30 to 70 wt %.

The ether-type naphthalene-based epoxy resin may be a mixture of ether-type naphthalene-based epoxy resins of the following Chemical Formulas 12-1 and 12-2:

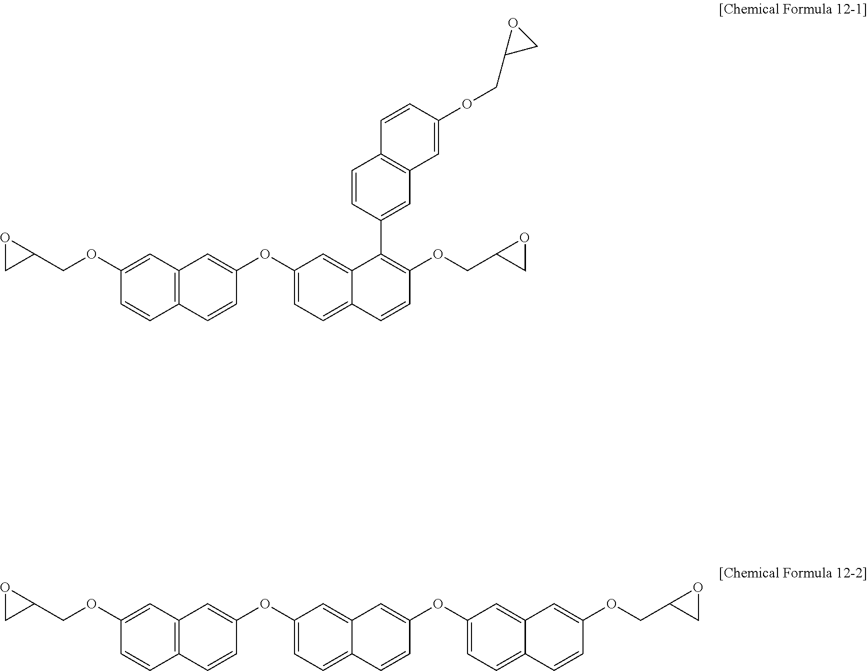 [SMILES: c1cc2ccc(Oc3ccc4ccc(OCC5CO5)c(-c5ccc6ccc(OCC7CO7)cc6c5)c4c3)cc2cc1OCC1CO1 ; c1cc2ccc(Oc3ccc4ccc(Oc5ccc6ccc(OCC7CO7)cc6c5)cc4c3)cc2cc1OCC1CO1]

A mixing weight ratio of the ether-type naphthalene-based epoxy resins of Chemical Formulas 12-1 and 12-2 may be 5:5 to 6:4.

The liquid crystal oligomer may have a number average molecular weight of 3,500 to 5,000 g/mol.

The structural unit of Chemical Formula 1 may be included in a content of 5 to 60 mol % based on a total amount of the liquid crystal oligomer, and the structural unit of Chemical Formula 2 may be included in a content of 40 to 95 mol % based on the total amount of the liquid crystal oligomer.

In Chemical Formula 4-7, L₁ may be an ether group, a sulfide group, a ketone group, a sulfoxide group, a sulfone group, an azo group, a cyanide group, a substituted or unsubstituted (C1-C20) alkylene group, a substituted or unsubstituted (C1-C20) alkenylene group, or a substituted or unsubstituted (C6-C30) arylene group.

In Chemical Formula 5-6, L₂ may be an ether group, a sulfide group, a ketone group, an amide group, a sulfoxide group, a sulfone group, an azo group, a cyanide group, a substituted or unsubstituted (C1-C20) alkylene group, a substituted or unsubstituted (C2-C20) alkenylene group, a substituted or unsubstituted (C6-C30) arylene group, a divalent organic functional group substituted or unsubstituted with at least one functional group of the following Chemical Formula 6, or a divalent organic functional group of the following Chemical Formulas 7-1 to 7-3.

The Chemical Formula 6 may be represented by the following Chemical Formula 9.

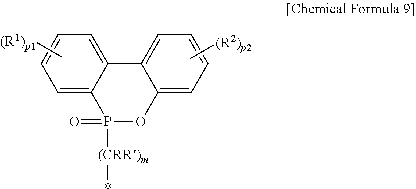

where R¹ and R² are the same as or different to each other and are each hydrogen, halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, or Z₁ (Z₁ is the same as in Chemical Formula 1), p1 and p2 are integers of 0 to 4, R and R′ are the same as or different to each other and are each hydrogen, a (C1-C20) alkyl group, or a (C6-C30) aryl group, and m is an integer of 0 to 3.

The liquid crystal oligomer may be represented by the following Chemical Formula 10.

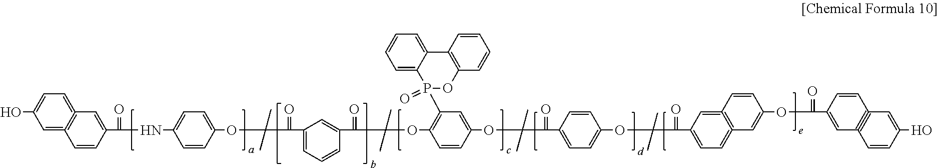

where a, b, c, d, and e refer to molar ratios of structural units and are determined in a number average molecular weight of the liquid crystal oligomer.

The resin composition for a printed circuit board may further contain a maleimide-based resin.

The maleimide-based resin may be represented by the following Chemical Formula 13:

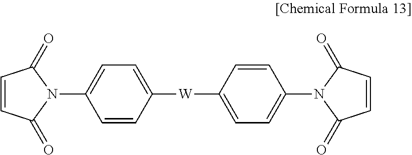

where W is a single bond, an ether group, a sulfide group, a ketone group, a sulfoxide group, a sulfone group, a substituted or unsubstituted (C1-C20) alkylene group, a substituted or unsubstituted (C2-C20) alkoxylene group, a substituted or unsubstituted (C6-C30) arylene group, or a substituted or unsubstituted (C6-C30) (hetero)arylene group including at least one of an ether group, a sulfide group, a ketone group, a sulfoxide group, a sulfone group, an amide group, and an ester group.

According to an exemplary embodiment in the present disclosure, a copper clad laminate may include: an insulating layer containing the resin composition as described above; and a copper foil formed on at least one of upper and lower surfaces of the insulating layer.

The insulating layer may further contain a reinforcing material.

According to an exemplary embodiment in the present disclosure, a printed circuit board may include: an insulating layer containing the resin composition as described above; and a circuit pattern formed on the insulating layer.

The insulating layer may further contain a reinforcing material.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view schematically illustrating a copper clad laminate (CCL) according to an exemplary embodiment of the present disclosure; and

FIG. 2 is a cross-sectional view schematically illustrating a printed circuit board according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

Unless otherwise described in the present specification, the term “substitution” means that a hydrogen atom of a compound or a functional group is substituted with halogen (F, Cl, Br, or I), a hydroxyl group, an alkoxy group, a nitro group, a cyano group, an amino group, an azido group, an amidino group, a hydrazino group, a hydrazono group, a carbonyl group, a carbamyl group, a thiol group, an ester group, a carboxylic group or a salt thereof, a sulfonic acid group or a salt thereof, phosphate or a salt thereof, a (C1-C20) alkyl group, a (C2-C16) alkynyl group, a (C6-C20) aryl group, a (C7-C13) arylalkyl group, a (C1-C4) oxyalkyl group, a (C1-C20) heteroalkyl group, a (C3-C20) heteroarylalkyl group, a (C3-C20) cycloalkyl group, a (C3-C15) cycloalkenyl group, a (C6-C15) cycloalkynyl group, a heterocycloalkyl group, or a combination thereof.

Unless otherwise described in the present specification, the term “hetero” means that 1 to 3 hetero atoms (N, O, S, Si, or P) are present in a ring.

Unless otherwise described in the present specification, the term “alicyclic group” refers to a (C3-C30) cycloalkyl group, a (C3-C30) cycloalkenyl group, a (C3-C30) cycloalkynyl group, a (C3-C30) heterocycloalkyl group, a (C3-C30) heterocycloalkenyl group, a (C3-C30) heterocycloalkynyl group, or the like.

Unless otherwise described in the present specification, the term “aromatic ring”, which indicates a functional group having a ring structure in which unsaturated bonds, lone pairs, or the like, are mixed and having an electron delocalization structure or an electron resonance structure, refers to a (C6-C30) aryl group, a (C2-C30) heteroaryl group, and a (C2-C30) heterocycloalkenyl group.

The resin composition for a printed circuit board according to an exemplary embodiment of the present disclosure may contain a liquid crystal oligomer and an ether-type naphthalene-based epoxy resin.

The liquid crystal oligomer according to an exemplary embodiment of the present disclosure, which performs a curing reaction together with the ether-type naphthalene-based epoxy resin in the composition, may include a structural unit of the following Chemical Formula 1 and a structural unit of the following Chemical Formula 2 and include a functional group of the following Chemical Formula E on at least one end thereof.

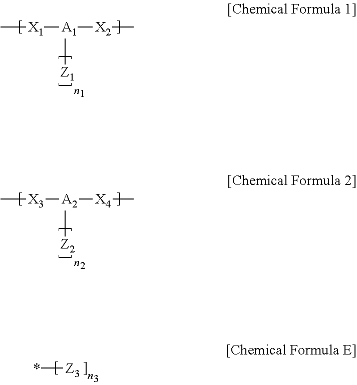

In Chemical Formulas 1, 2, and E, X₁ to X₄ are each independently the same as or different to each other and may be C(═O)O, O, C(═O)NR, NR′, or CO, where R and R′ are each independently the same as or different to each other and are hydrogen, a substituted or unsubstituted (C1-C20) alkyl group or a substituted or unsubstituted (C6-C30) aryl group).

Z₁ to Z₃ may each be independently a hydroxyl group; a thiol group; a substituted or unsubstituted maleimide group; a substituted or unsubstituted nadimide group; a substituted or unsubstituted tetrahydrophthalimide group; a substituted or unsubstituted (C2-C30) alkenyl group; a substituted or unsubstituted (C2-C30) alkynyl group; a substituted or unsubstituted propagyl ether group; a substituted or unsubstituted benzocyclobutene group; a (iso)cyanate group; a cyanide group; a substituted or unsubstituted (C3-C30) alicyclic group having a double or triple bond; a substituted or unsubstituted (C3-C30) hetero atom-containing alicyclic group having a double or triple bond; a (C3-C30) alicyclic group including a (C2-C30) alkenyl group or (C2-C30) alkynyl group; a (C3-C30) hetero atom-containing alicyclic group including a (C2-C30) alkenyl group or (C2-C30) alkynyl group; a (C6-C30) aryl group including a (C2-C30) alkenyl group or (C2-C30) alkynyl group; a (C6-C30) aryl group having a (iso)cyanate group or cyanide group; or a combination thereof.

Here, n1 to n3 are each independently integers of 0 to 3, and n1+n2+n3 may be 1 or more.

In Chemical Formula 1, A₁ may be one of functional groups represented by the following Chemical Formulas 4-1 to 4-7. In A₁, binding groups at both sides of an aromatic ring bonded to a main chain may be positioned in an ortho or meta position. An aromatic structural unit having a kink structure as described above may be repeatedly introduced in the main chain of the liquid crystal oligomer. Since linearity of the main chain of the liquid crystal oligomer may be decreased due to introduction of the kink structure, interactions between the main chains and crystallinity may be decreased, such that solubility for a solvent may be improved.

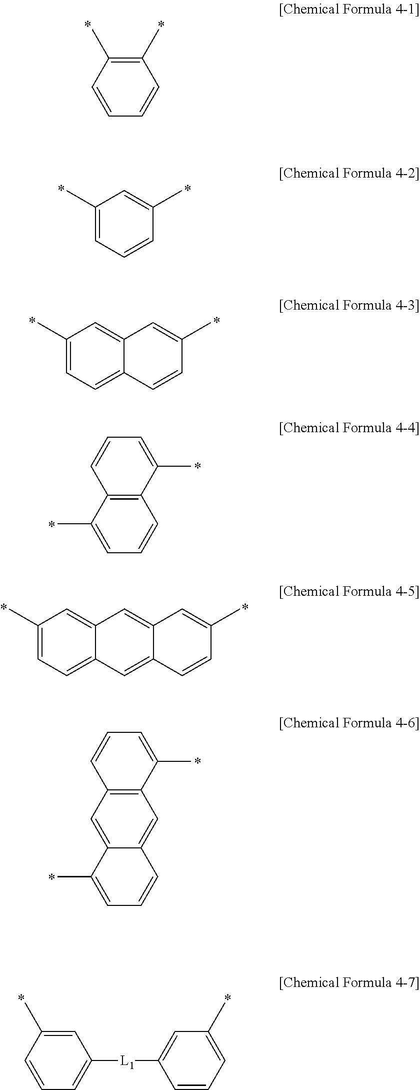

In Chemical Formula 4-7, L₁ is a divalent organic functional group, and in Chemical Formulas 4-1 to 4-7, at least one hydrogen atom of each aromatic ring may be substituted with halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, or Z₁ (Z₁ is the same as in Chemical Formula 1).

In Chemical Formula 2, A₂ is one of functional groups represented by the following Chemical Formulas 5-1 to 5-6 or a (C2-C20) alkylene group having a functional group of the following Chemical Formula 6.

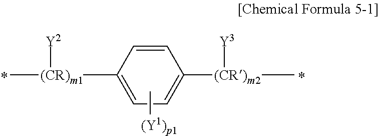

In Chemical Formula 5-1, Y¹ to Y³ are each independently the same as or different to each other and are each hydrogen, a (C1-C10) alkyl group, or a functional group of the following Chemical Formula 6, at least one of Y¹ to Y³ being the functional group of the following Chemical Formula 6, p1 is an integer of 0 to 4, m1 and m2 are the same or different and are integers of 0 to 3, p1, m1, and m2 are not simultaneously 0, and R and R′ are hydrogen or a (C1-C10) alkyl group.

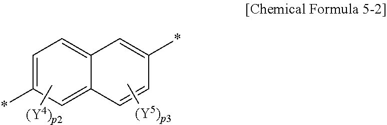

In Chemical Formula 5-2, Y⁴ and Y⁵ are the same as or different to each other and are each hydrogen, a (C1-C10) alkyl group, or a functional group of the following Chemical Formula 6, at least one of Y⁴ and Y⁵ being the functional group of the following Chemical Formula 6, and p2 and p3 are integers of 0 to 3 but are not simultaneously 0.

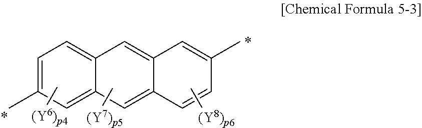

In Chemical Formula 5-3, Y⁶ to Y⁸ are the same as or different to each other and are each hydrogen, a (C1-C10) alkyl group, or a functional group of the following Chemical Formula 6, at least one of Y⁶ to Y⁸ being the functional group of the following Chemical Formula 6, p4 and p6 are integers of 0 to 3, p5 is an integer of 0 to 2, and p4, p5, and p6 are not simultaneously 0.

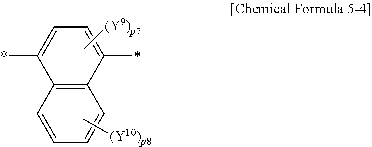

In Chemical Formula 5-4, Y⁹ and Y¹⁰ are the same as or different to each other and are each hydrogen, a (C1-C10) alkyl group, or a functional group of the following Chemical Formula 6, at least one of Y⁹ and Y¹⁰ being the functional group of the following Chemical Formula 6, and p7 and p8 are integers of 0 to 2 but are not simultaneously 0.

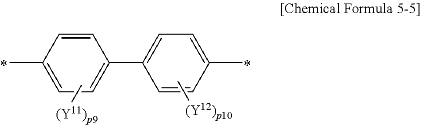

In Chemical Formula 5-5, Y¹¹ and Y¹² are the same as or different to each other and are each hydrogen, a (C1-C10) alkyl group, or a functional group of the following Chemical Formula 6, at least one of Y¹¹ and Y¹² being the functional group of the following Chemical Formula 6, and p9 and p10 are integers of 0 to 4 but are not simultaneously 0.

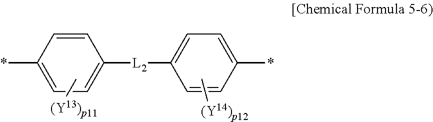

In Chemical Formula 5-6, Y¹³ and Y¹⁴ are the same as or different to each other and are each hydrogen, a (C1-C10) alkyl group, or a functional group of the following Chemical Formula 6, at least one of Y¹³ and Y¹⁴ being the functional group of the following Chemical Formula 6, p11 and p12 are integers of 0 to 4, L₂ is an ether group, a sulfide group, a ketone group, an amide group, a sulfoxide group, a sulfone group, an azo group, a cyanide group, a substituted or unsubstituted (C1-C20) alkylene group, a substituted or unsubstituted (C2-C20) alkenylene group, a substituted or unsubstituted (C6-C30) arylene group, a divalent organic functional group substituted or unsubstituted with at least one functional group of the following Chemical Formula 6, or a divalent organic functional group of the following Chemical Formulas 7-1 to 7-3, and in the case in which L₂ is not substituted with the functional group of the following Chemical Formula 6, one of p11 and p12 is not 0.

In Chemical Formulas 5-1 and 5-6, at least one hydrogen atom of each aromatic ring may be substituted with halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, or Z₁ (Z₁ is the same as in Chemical Formula 1).

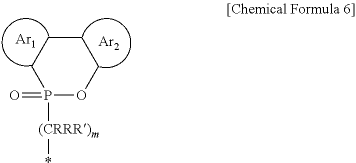

In chemical Formula 6, Ar₁ and Ar₂ are substituted or unsubstituted (C4-C30) aromatic ring groups, R and R′ are the same as or different to each other and are each hydrogen, a (C1-C20) alkyl group, or a (C6-C30) aryl group, and m is an integer of 0 to 3.

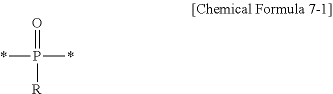

In Chemical Formula 7-1, R is hydrogen, halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, or a substituted or unsubstituted (C6-C30) aryloxy group.

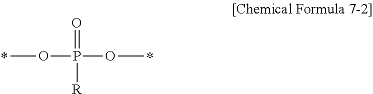

In Chemical Formula 7-2, R is hydrogen, halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, or a substituted or unsubstituted (C6-C30) aryloxy group.

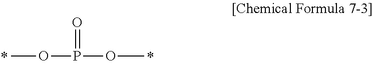

In Chemical Formula 4-7, L₁ is an ether group, a sulfide group, a ketone group, a sulfoxide group, a sulfone group, an azo group, a cyanide group, a substituted or unsubstituted (C1-C20) alkylene group, a substituted or unsubstituted (C1-C20) alkenylene group, a substituted or unsubstituted (C6-C30) arylene group, or the like. As a specific example, L₁ may be any one of functional groups represented by the following Chemical Formulas 8-1 to 8-10.

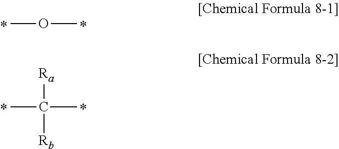

In Chemical Formula 8-2, Rₐ and R_{b} may each be independently hydrogen, halogen, a (C1-C5) alkyl group, a (C1-C5) haloalkyl group, or Z₁ (Z₁ is the same as in Chemical Formula 1).

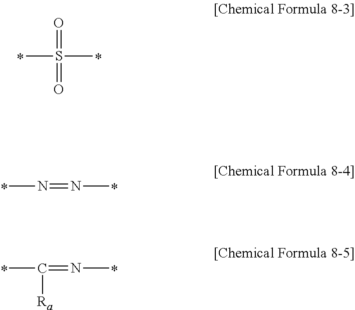

In Chemical Formula 8-5, Rₐ is hydrogen, halogen, a (C1-C5) alkyl group, a (C1-C5) haloalkyl group, or Z₁ (Z₁ is the same as in Chemical Formula 1).

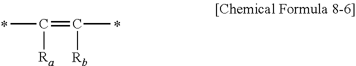

In Chemical Formula 8-6, Rₐ and R_{b} are each independently hydrogen, halogen, a (C1-C5) alkyl group, a (C1-C5) haloalkyl group, or Z₁ (Z₁ is the same as in Chemical Formula 1).

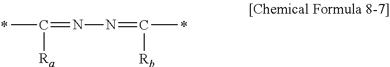

In Chemical Formula 8-7, Rₐ and R_{b} are each independently hydrogen, halogen, a (C1-C5) alkyl group, a (C1-C5) haloalkyl group, or Z₁ (Z₁ is the same as in Chemical Formula 1).

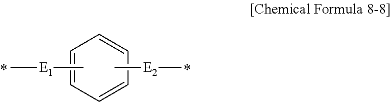

In Chemical Formula 8-8, E₁ and E₂ are the same as or different to each other and are linkage groups selected from a group consisting of a single bond, an ether group, an ester group, a ketone group, a sulfide group, a sulfoxide group, and a sulfone group.

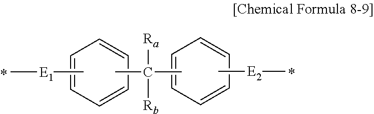

In Chemical Formula 8-9, Rₐ and R_{b} are each independently hydrogen, halogen, a (C1-C5) alkyl group, a (C1-C5) haloalkyl group, or Z₁ (Z₁ is the same as in Chemical Formula 1), and E₁ and E₂ are the same as or different to each other and are linkage groups selected from a group consisting of a single bond, an ether group, an ester group, a ketone group, a sulfide group, a sulfoxide group, and a sulfone group.

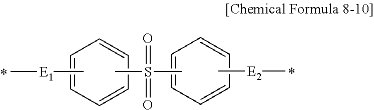

In Chemical Formula 8-10, E₁ and E₂ are each independently linkage groups selected from a group consisting Of a single bond, an ether group, an ester group, a ketone group, a sulfide group, a sulfoxide group, and a sulfone group.

In Chemical Formulas 8-8 to 8-10, at least one hydrogen atom of each aromatic ring may be substituted with halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, or Z₁ (Z₁ is the same as in Chemical Formula 1).

In Chemical Formula 5-6, L₂ is an ether group, a sulfide group, a ketone group, an amide group, a sulfoxide group, a sulfone group, an azo group, a cyanide group, a substituted or unsubstituted (C1-C20) alkylene group, a substituted or unsubstituted (C2-C20) alkenylene group, a substituted or unsubstituted (C6-C30) arylene group, a divalent organic functional group substituted or unsubstituted with at least one functional group of Chemical Formula 6, or a divalent organic functional group of Chemical Formulas 7-1 to 7-3.

As a specific example, L₂ may be any one of functional groups represented by Chemical Formulas 8-1 to 8-10. In Chemical Formulas 8-2, 8-5, 8-6, 8-7, and 8-9, Rₐ and R_{b} are each independently hydrogen, halogen, a (C1-C5) alkyl group, a (C1-C5) haloalkyl group, Z₁ (Z₁ is the same as in Chemical Formula 1), or a functional group of Chemical Formula 6, and in Chemical Formulas 8-8 to 8-10, at least one hydrogen atom of each aromatic ring may be substituted with halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, Z₁ (Z₁ is the same as in Chemical Formula 1), or a functional group of Chemical Formula 6.

The Chemical Formula 6 may be represented by the following Chemical Formula 9.

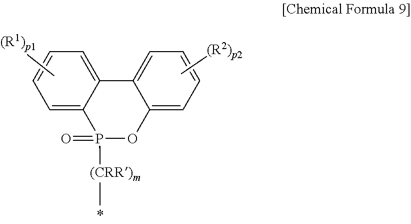

In Chemical Formula 9, R¹ and R² are the same as or different to each other and are each hydrogen, halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, or Z₁ (Z₁ is the same as in Chemical Formula 1), p1 and p2 are integers of 0 to 4, R and R′ are the same as or different to each other and are each hydrogen, a (C1-C20) alkyl group, or a (C6-C30) aryl group, and m is an integer of 0 to 3.

According to an exemplary embodiment of the present disclosure, the liquid crystal oligomer may include a hydroxyl group at one or more of side chains or ends thereof. In addition, the liquid crystal oligomer may include a functional group containing phosphorus at the main chain or side chain. According to an exemplary embodiment of the present disclosure, the liquid crystal oligomer includes the hydroxyl group at one or more of the side chains and the ends thereof, such that an insulating resin composition may be cured by a crosslinking reaction of the liquid crystal oligomer and the epoxy resin instead of a crosslinking reaction between the liquid crystal oligomers. Further, in the case in which the liquid crystal oligomer includes the functional group containing phosphorus at the main chain or side chain, flame retardancy of the insulating resin composition may be further improved.

The liquid crystal oligomer according to an exemplary embodiment of the present disclosure may be represented by the following Chemical Formula 10.

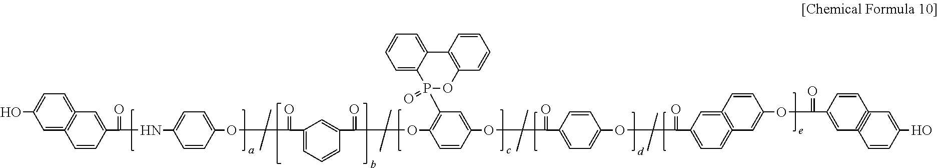

In Chemical Formula 10, a, b, c, d, and e may refer to molar ratios of structural units and be determined according to contents of starting materials.

The molar ratios of the structural units of the liquid crystal oligomer are not particularly limited, but a, b, c, d, and e may be determined within a preferable number average molecular weight of the liquid crystal oligomer.

The liquid crystal oligomer represented by Chemical Formula 10 may include a hydroxyl group at both ends thereof and a functional group containing phosphorus at a side chain thereof. The liquid crystal oligomer represented by Chemical Formula 10 is included, such that solubility may be improved, and the insulating resin composition may be cured by the crosslinking reaction of the liquid crystal oligomer and the epoxy resin instead of the crosslinking reaction between the liquid crystal oligomers, thereby improving mechanical properties.

The liquid crystal oligomer may have a number average molecular weight of 3,500 to 5,000 g/ml. In the case in which the liquid crystal oligomer may have a number average molecular weight in the above-mentioned range, the liquid crystal oligomer may have a suitable crosslinking density and excellent solubility for a solvent, such that a solid content may be sufficient at the time of impregnation in a network structure for preparing a prepreg, thereby securing excellent physical properties.

The structural unit of Chemical Formula 1 may be included in a content of 5 to 60 mol % based on a total amount of the liquid crystal oligomer, and the structural unit of Chemical Formula 2 may be included in a content of 40 to 95 mol % based on the total amount of the liquid crystal oligomer.

In the case in which the structural unit of Chemical

Formula 1 and the structural unit of Chemical Formula 2 are included at the above-mentioned range, solubility of the liquid crystal oligomer may be improved. In addition, the insulating resin composition may be cured without the crosslinking reaction in the liquid crystal oligomer, such that mechanical properties may be improved.

According to an exemplary embodiment of the present disclosure, the liquid crystal oligomer may be contained in a content of 20 to 70 wt % in the entire resin composition for a printed circuit board. In the case in which the content of the liquid crystal oligomer is less than 20 wt %, thermal characteristics may be deteriorated, and in the case in which the content is more than 70 wt %, chemical resistance may be deteriorated.

The resin composition for a printed circuit board according to an exemplary embodiment of the present disclosure may contain an ether-type naphthalene-based epoxy resin represented by the following Chemical Formula N.

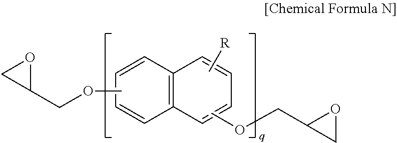

In Chemical Formula N, q is an integer of 2 to 5, and R is each independently hydrogen or one of functional groups represented by the following Chemical Formula 11.

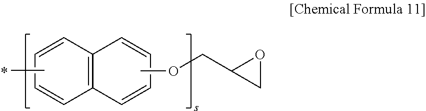

In Chemical Formula 11, s is an integer of 1 to 5.

The ether-type naphthalene-based epoxy resin in which at least two naphthalene units are bonded by ether (—O—) bonds may be easily packed after thermosetting to thereby form a dense stacking structure. Therefore, deformation by heat may be small, and the ether-type naphthalene-based epoxy resin may be thermally stable.

In addition, the ether-type naphthalene-based epoxy resin may be bonded to the hydroxyl group of the liquid crystal oligomer to configure a network in which the liquid crystal oligomer and the ether-type naphthalene-based epoxy resin are linked to each other, thereby decreasing a coefficient of thermal expansion, increasing a glass transition temperature, and improving thermal resistance.

The ether-type naphthalene-based epoxy resin may be contained in a content of 30 to 70 wt % in the entire resin composition for a printed circuit board.

In the case in which the content of the ether-type naphthalene-based epoxy resin is less than 30 wt %, thermal characteristics, adhesive force, and flame retardancy may be deteriorated, and in the case in which the content is more than 70 wt %, advantageous of the liquid crystal oligomer, a maleimide-based resin, and the like, may be deteriorated, such that physical properties may be entirely deteriorated.

Ether-type naphthalene-based epoxy resins represented by the following Chemical Formulas 12-1 and 12-2 may be mixed and included in the ether-type naphthalene-based epoxy resin according to an exemplary embodiment of the present disclosure.

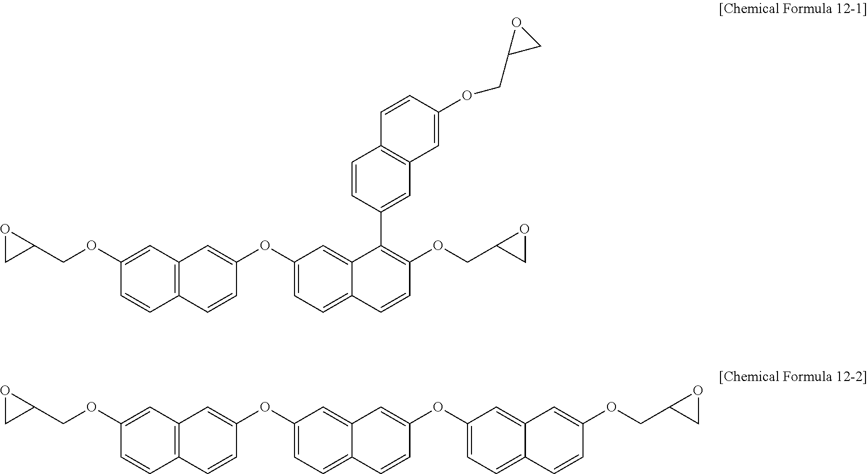 [SMILES: c1cc2ccc(Oc3ccc4ccc(OCC5CO5)c(-c5ccc6ccc(OCC7CO7)cc6c5)c4c3)cc2cc1OCC1CO1 ; c1cc2ccc(Oc3ccc4ccc(Oc5ccc6ccc(OCC7CO7)cc6c5)cc4c3)cc2cc1OCC1CO1]

The ether-type naphthalene-based epoxy resins of Chemical Formulas 12-1 and 12-2 may be included at a mixing weight ratio of 5:5 to 6:4.

In the case in which the ether-type naphthalene-based epoxy resins of Chemical Formulas 12-1 and 12-2 are included at a mixing weight ratio within the above-mentioned range, thermal characteristics such as the coefficient of thermal expansion, or the like, and flame retardancy may be improved.

Meanwhile, the resin composition for a printed circuit board according to an exemplary embodiment of the present disclosure may further contain the maleimide-based resin.

The maleimide-based resin may serve as a crosslinker and be bismaleimide. In detail, the maleimide-based resin may be represented by the following Chemical Formula 13.

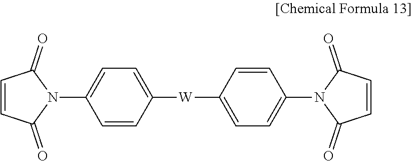

In Chemical Formula 13, W is a single bond, an ether group, a sulfide group, a ketone group, a sulfoxide group, a sulfone group, a substituted or unsubstituted (C1-C20) alkylene group, a substituted or unsubstituted (C2-C20) alkoxylene group, a substituted or unsubstituted (C6-C30) arylene group, or a substituted or unsubstituted (C6-C30) (hetero)arylene group including at least one of an ether group, a sulfide group, a ketone group, a sulfoxide group, a sulfone group, an amide group, and an ester group.

The maleimide based resin may be contained in a content of 10 to 50 wt % in the entire resin composition for a printed circuit board. In the case in which the content of the maleimide-based resin is less than 10 wt %, an effect of improving thermal characteristics such as improvement of the glass transition temperature, or the like, may be insignificant, and in the case in which the content is more than 50 wt %, the resin composition may be brittle, such that adhesive force may be deteriorated.

The resin composition for a printed circuit board according to an exemplary embodiment of the present disclosure may further contain a curing catalyst.

An example of the curing catalyst may include 2-methylimidazole, 2-phenylimidazole, 2-phenyl-4-phenyl imidazole, bis(2-ethyl-4-methylimidazole), 2-phenyl-4-methyl-5-hydroxymethylimidazole, 2-phenyl-4,5-dihydroxymethylimidazole, triazine added imidazole, anhydrous methylnadic acid, dicyandiamide, phthalic acid anhydride, tetrahydrophthalic acid anhydride, methylbutyltetrahydro phthalic acid anhydride, hexahydro phthalic acid anhydride, methylhydrophthalic acid anhydride, trimethylic acid anhydride, pyromethalic acid anhydride, benzophenonetetracarboxlic acid anhydride, and the like, and a mixture thereof may be used, but the present disclosure is not limited thereto.

The curing catalyst may be contained in a content of 0.1 to 0.5 wt % in the entire resin composition for a printed circuit board. In the case in which the content of the curing catalyst is less than 0.1 wt %, the crosslinking reaction may be deteriorated, and in the case in which the content is more than 0.5 wt %, thermal resistance may be deteriorated.

The resin composition for a printed circuit board according to an exemplary embodiment of the present disclosure may further contain a solvent.

As the solvent, a polar aprotic solvent may be used. For example, a halogen-based solvent such as 1-chlorobutane, chlorobenzene, 1,1-dichloroethane, 1,2-dichloroethane, chloroform, 1,1,2,2-tetrachloroethane, or the like; an ether-based solvent such as diethylether, tetrahydrofuran, 1,4-dioxane, or the like; a ketone-based solvent such as methylethylketone (MEK), acetone, cyclohexane, or the like; an acetate-based solvent such as propylene glycol monomethyl ether acetate (PGMEA), or the like; an ester-based solvent such as ethyl acetate, or the like; a lactone-based solvent such a s γ-butyrolactone, or the like; a carbonate-based solvent such as ethylene carbonate, propylene carbonate, or the like; an amine-based solvent such as triethylamine, pyridine, or the like; a nitrile-based solvent such as acetonitrile, or the like; an amide-based solvent such as N,N′-dimethylformamide (DMF), N,N′-dimethylacetamide (DMAc), tetramethyl urea, N-methylpyrrolidone (NMP), or the like; a nitro-based solvent such as nitromethane, nitrobenzene, or the like; a sulfide-based solvent such as dimethyl sulfoxide (DMSO), sulfolane, or the like; a phosphate-based solvent such as hexamethylphosphoramide, tri-n-butyl phosphate, or the like; or a combination thereof may be used, but the present disclosure is not limited thereto.

In addition, the resin composition for a printed circuit board according to an exemplary embodiment of the present disclosure may further contain additives such as a filler, a softener, a plasticizer, an antioxidant, a flame retardant, a flame retardant adjuvant, a lubricant, an antistatic agent, a colorant, a heat stabilizer, alight stabilizer, a UV absorbent, a coupling agent, a precipitation preventing agent, or the like.

As the filler, an organic filler or inorganic filler may be used. An example of the organic filler includes epoxy resin powder, melamine resin powder, urea resin powder, benzoguanamine resin powder, styrene resin, and the like, but is not limited thereto. An example of the inorganic filler may include natural silica, fused silica, amorphous silica, hollow silica, aluminum hydroxide, boehmite, magnesium hydroxide, molybdenum oxide, zinc molybdate, zinc borate, zinc stannate, aluminum borate, potassium titanate, magnesium sulfate, silicon carbide, zinc oxide, silicon nitride, silicon oxide, aluminum titanate, barium titanate, barium strontium titanate, aluminum oxide, alumina, clay, kaolin, talc, calcined clay, calcined kaolin, calcined talc, mica, short glass fibers, and the like, but is not particularly limited thereto. One or a mixture of at least two of the organic fillers and inorganic fillers may be used.

An example of the plasticizer may include polyethylene glycol, a polyamide oligomer, ethylenebis stearamide, phthalic acid ester, a polystyrene oligomer, liquid paraffin, polyethylene wax, silicone oil, and the like, but is not limited thereto. One or a mixture of at least two thereof may be used.

An example of the antioxidant may include a phosphorus containing antioxidant, a phenol-based antioxidant, a sulfur containing antioxidant, and the like, but is not limited thereto. One or a mixture of at least two thereof may be used.

The resin composition for a printed circuit board according to an exemplary embodiment of the present disclosure may be prepared by blending the components by various methods such as mixing at room temperature, melt mixing, or the like.

As described above, an insulating layer of a printed circuit board may be formed of the resin composition according to an exemplary embodiment of the present disclosure. More specifically, although not limited, the insulating layer may be formed on a substrate by casting the resin composition for a printed circuit board on the substrate to form a thin film and removing a solvent. Examples of the substrate may include metal foil such as copper foil, aluminum foil, gold foil, silver foil, or the like, a glass substrate, a polyethylene terephthalate (PET) film, or the like.

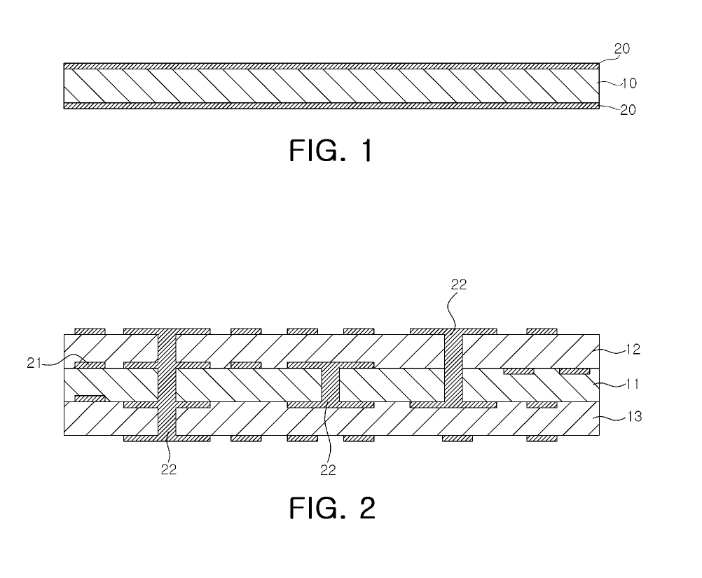

Then, FIG. 1 is a cross-sectional view schematically illustrating a copper clad laminate (CCL) according to an exemplary embodiment of the present disclosure.

The printed circuit board according to an exemplary embodiment of the present disclosure may be formed by laminating the copper clad laminate.

Referring to FIG. 1, the CCL may include an insulating layer 10 and copper foils 20 formed on both surfaces of the insulating layer.

In addition, although not shown, the copper foil may be formed on only one surface of the insulating layer.

The insulating layer 10 may be formed of the resin composition for a printed circuit board according to an exemplary embodiment of the present disclosure as described above or may be formed of a prepreg containing the resin composition for a printed circuit board and a reinforcing material.

The copper foil 20 may be formed on the insulating layer 10, and then thermal treatment may be performed, such that the CCL may be formed. A circuit pattern may be formed by patterning the copper foil 20 of the CCL.

FIG. 2 is a cross-sectional view schematically illustrating a printed circuit board according to an exemplary embodiment of the present disclosure.

Referring to FIG. 2, the printed circuit board according to the present exemplary embodiment may include insulating layers 11 to 13; and circuit patterns 21 and 22 formed on one surface or both surfaces of the insulating layers. More specifically, a board body may be formed by laminating a first insulating layer 11 and laminating second and third insulating layers 12 and 13 on upper and lower surfaces of the first insulating layer 11, respectively. In addition, horizontal signal lines 21 and via electrodes connecting the horizontal signal lines to each other may be formed on the first to third insulating layers 11 to 13.

Although a printed circuit board having a four-layer structure is described in the present exemplary embodiment, the printed circuit board is not limited thereto, but the printed circuit board may be a single layer wiring board or multilayer wiring board having two or more layers according to the number of laminated insulating layers and formed circuit pattern.

The circuit patterns 21 and 22 may be formed on the insulating layers 11 to 13 by plating, or the like, and then laminated, such that the printed circuit board may be formed.

In addition, the insulating layers 11 to 13 of the printed circuit board may be formed of the prepreg containing the resin composition for a printed circuit board and the reinforcing material.

The prepreg may be formed by mixing the resin composition for a printed circuit board and the reinforcing material. More specifically, the prepreg may be prepared by applying or impregnating the resin composition for a printed circuit board into the reinforcement, curing the resultant, and then removing a solvent. An example of the impregnation method includes a dip coating method, a roll coating method, or the like, but is not limited thereto.

Examples of the reinforcing material include woven glass cloth, woven alumina glass cloth, non-woven glass fabric, non-woven cellulose fabric, woven carbon cloth, polymer cloth, and the like. Further, the examples of the reinforcing material may further include glass fiber, silica glass fiber, carbon fiber, alumina fiber, silicon carbide fiber, asbestos, rock wool, mineral wool, gypsum whisker, and a woven or non-woven fabric thereof, aromatic polyamide fiber, polyimide fiber, liquid crystal polyester, polyester fiber, fluorinated fiber, polybenzoxazole fiber, glass fiber including polyamide fiber, glass fiber including carbon fiber, glass fiber including polyimide fiber, glass fiber including aromatic polyester, glass paper, mica paper, alumina paper, craft paper, cotton paper, paper-glass bond paper, and the like. At least one thereof may be mixed and used.

Hereinafter, Inventive Examples will be described in order to assist in the understanding of the present disclosure. Inventive Examples of the present disclosure are provided in order to more completely explain the present disclosure to those skilled in the art. The following Inventive Example may be modified in several different forms and does not limit a scope of the present disclosure. Rather, these Inventive Examples are provided in order to make this disclosure more thorough and complete and completely transfer ideas of the present disclosure to those skilled in the art.

### Inventive Example

30 wt % of a liquid crystal oligomer (number average molecular weight: 3900 g/mol) represented by the following Chemical Formula 10, 40 wt % of a mixed ether-type naphthalene-based epoxy resin represented by the following Chemical Formulas 12-1 and 12-2 (mixing weight ratio: 6:4), 29.6 wt % of bismaleimide, and 0.4 wt % of dicyandiamide (curing catalyst) were added to N,N′-dimethylacetamide (DMAc) so that a solid content became 53 wt %, thereby preparing a resin composition vanish for a printed circuit board.

A suitable amount of the vanish was poured onto one surface of copper foil at a thickness of 150 μm, thereby preparing a film. After the film was put into an oven and primarily dried at 80° C. for 30 minutes to volatilize the solvent, the primarily dried film was secondarily dried at 120° C. for 60 minutes, such that the film was semi-cured.

When the film was completely dried, a temperature was raised to 220° C., and then the film was maintained at 220° C. and a pressure of 30 kgf/cm² for 90 minutes, thereby completely curing the film. The pressure of 30 kgf/cm² was applied since the temperature reached at 40° C. The cured film was cut at a size of 4.3 mm×30 mm, thereby preparing a test sample.

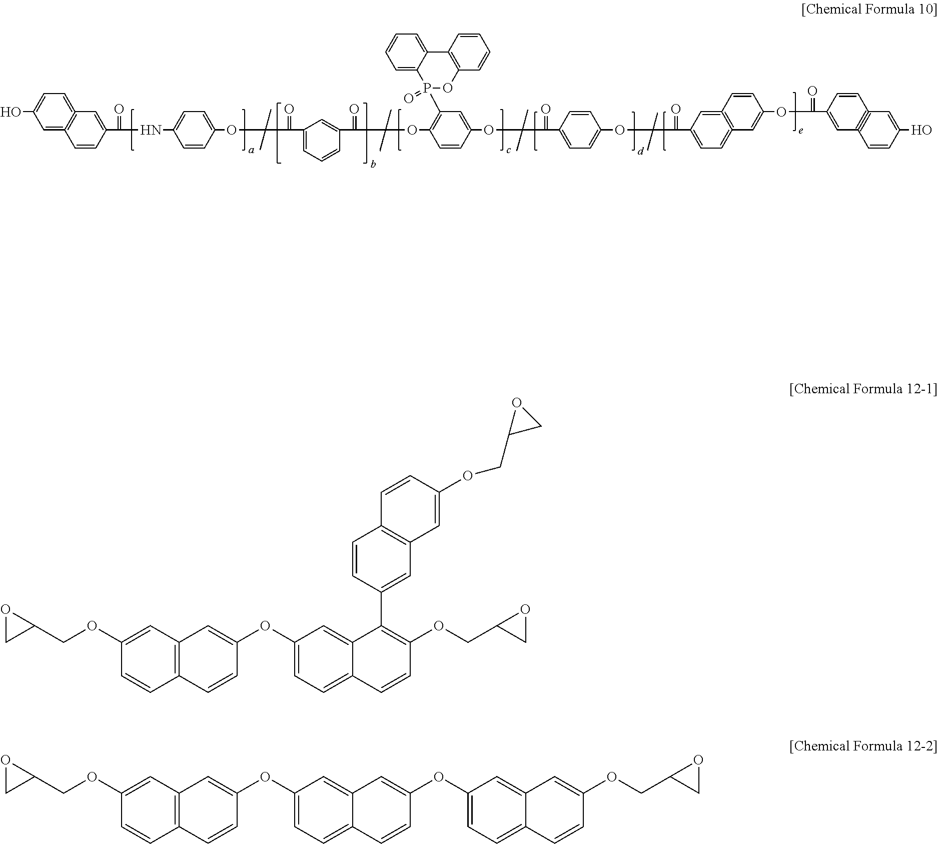

### Comparative Example 1

A test sample was prepared by the same method as in Inventive Example except for adding 60 wt % of the liquid crystal oligomer of Inventive Example, 39.6 wt % of N,N,N′,N′-Tetraglycidyl-4,4′-methylene bisbenzenamine, and 0.4 wt % of dicyandiamide (curing catalyst) to N,N′-dimethylacetamide (DMAc) so that a solid content became 63 wt % to prepare a resin composition vanish for a printed circuit board.

### Comparative Example 2

A test sample was prepared by the same method as in Inventive Example except for adding 60 wt % of the liquid crystal oligomer of Inventive Example, 39.6 wt % of a naphthalene base epoxy of the following Chemical Formula 14, and 0.4 wt % of dicyandiamide (curing catalyst) to N,N′-dimethylacetamide (DMAc) so that a solid content became 63 wt % to prepare a resin composition vanish for a printed circuit board.

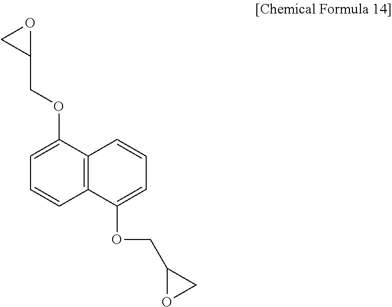 [SMILES: c1cc(OCC2CO2)c2cccc(OCC3CO3)c2c1]

### Experimental Example

Coefficients of thermal expansion (CTE) of the prepared test samples in Inventive Example and Comparative Examples 1 and 2 were measured by primarily raising a temperature to 300° C. at a rate of 10° C./min using a thermomechanical analyzer (TMA, TA Instruments TMA Q400) and secondarily raising the temperature to 310° C. at a rate of 10° C./min after cooling to calculate CTE(α1) and CTE(α2) of secondarily measured data. A glass transition temperature (Tg) was determined by raising a temperature to 350° C. at a rate of 3° C./min using Thermogravimetric Analysis (TGA, TA Instruments TGA DTA Q600) and calculating the maximum value of tan δ (a ratio of a loss modulus to a storage modulus).

The measurement results of the CTE and Tg were shown in Table 1.

TABLE 1

| | CTE(α1) (ppm/° C.) | CTE(α2) (ppm/° C.) | Tg (° C.) |
|---|---|---|---|
| Inventive | 46 | 110 | 270 |
| Example | | | |
| Comparative | 47 | 164 | 247 |
| Example 1 | | | |
| Comparative | 46 | 145 | 250 |
| Example 2 | | | |

Referring to Table 1, in the film of Inventive Example prepared by the resin composition for a printed circuit board according to an exemplary embodiment of the present disclosure, the CTE was low, and Tg was high, such that thermal characteristics were improved.

Particularly, it may be appreciated that as compared to the film of Comparative Example 2 containing the epoxy resin of Chemical Formula 14, in the case of the film of the Inventive Example containing an ether-type naphthalene-based epoxy resin in which at least two naphthalene units were bonded by an ether bond (—O—) at the mixing weight ratio, CTE was decreased and Tg was improved.

As set forth above, according to exemplary embodiments of the present disclosure, the resin composition for a printed circuit board may improve the CTE and the thermal characteristics (glass transition temperature and thermal decomposition temperature) of the prepreg, such that the printed circuit board having excellent thermal resistance and linear expansion characteristics among thin high-density circuit boards may be provided.

Further, the printed circuit board according to an exemplary embodiment of the present disclosure may have excellent thermal resistance and mechanical strength, and low permittivity and hygroscopicity may be secured. In addition, the printed circuit board may have excellent adhesive strength and satisfy a burying property of the pattern, solder heat and moisture resistance, as well as electrical properties, dimensional stability, chemical resistance, and mechanical properties may be excellent.

While exemplary embodiments have been shown and described above, it will be apparent to those skilled in the art that modifications and variations could be made without departing from the spirit and scope of the present disclosure as defined by the appended claims.

What is claimed is:

1. A resin composition for a printed circuit board comprising:
a liquid crystal oligomer including a structural unit of the following Chemical Formula 1 and a structural unit of the following Chemical Formula 2 and including a functional group of the following Chemical Formula E on at least one end; and
an ether-type naphthalene-based epoxy resin of Chemical Formula N: 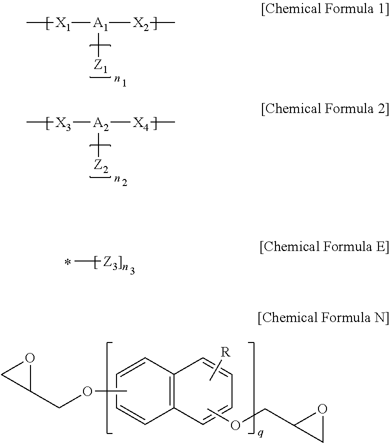
where X₁ to X₄ are each independently the same as or different to each other and are C(═O)O, O, C(═O)NR, NR′, or CO, R and R′ are each independently the same as or different to each other and are hydrogen, a substituted or unsubstituted (C1-C20) alkyl group or a substituted or unsubstituted (C6-C30) aryl group),
Z₁ to Z₃ are each independently a hydroxyl group; a thiol group; a substituted or unsubstituted maleimide group; a substituted or unsubstituted nadimide group; a substituted or unsubstituted tetrahydrophthalimide group; a substituted or unsubstituted (C2-C30) alkenyl group; a substituted or unsubstituted (C2-C30) alkynyl group; a substituted or unsubstituted propagyl ether group; a substituted or unsubstituted benzocyclobutene group; a (iso)cyanate group; a cyanide group; a substituted or unsubstituted (C3-C30) alicyclic group having a double or triple bond; a substituted or unsubstituted (C3-C30) hetero atom-containing alicyclic group having a double or triple bond; a (C3-C30) alicyclic group including a (C2-C30) alkenyl group or (C2-C30) alkynyl group; a (C3-C30) hetero atom-containing alicyclic group including a (C2-C30) alkenyl group or (C2-C30) alkynyl group; a (C6-C30) aryl group including a (C2-C30) alkenyl group or (C2-C30) alkynyl group; a (C6-C30) aryl group having a (iso)cyanate group or cyanide group; or a combination thereof,
n1 to n3 are each independently integers of 0 to 3, and n1+n2+n3 is 1 or more, and
A₁ is one of functional groups represented by the following Chemical Formulas 4-1 to 4-7, 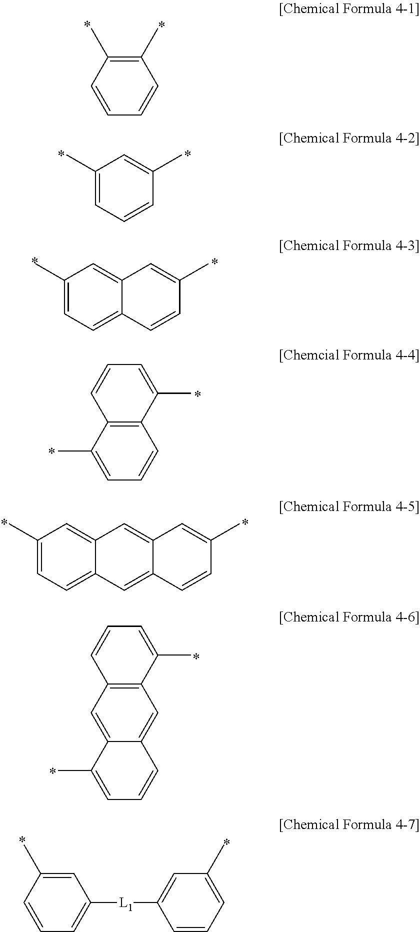
where L₁ is a divalent organic functional group, and
at least one hydrogen atom of each aromatic ring is substituted with halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, or Z₁ (Z₁ is the same as in Chemical Formula 1), and
A₂ is one of functional groups represented by the following Chemical Formulas 5-1 to 5-6 or a (C2-C20) alkylene group having a functional group of the following Chemical Formula 6, 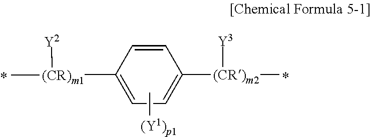
where Y¹ to Y³ are each independently the same as or different to each other and are each hydrogen, a (C1-C10) alkyl group, or a functional group of the following Chemical Formula 6, at least one of Y¹ to Y³ being the functional group of the following Chemical Formula 6, p1 is an integer of 0 to 4, m1 and m2 are the same or different and are integers of 0 to 3, p1, m1, and m2 are not simultaneously 0, and R and R′ are hydrogen or a (C1-C10) alkyl group, 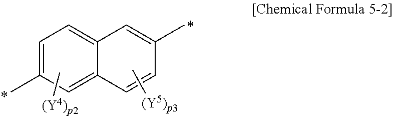
where Y⁴ and Y⁵ are the same as or different to each other and are each hydrogen, a (C1-C10) alkyl group, or a functional group of the following Chemical Formula 6, at least one of Y⁴ and Y⁵ being the functional group of the following Chemical Formula 6, and p2 and p3 are integers of 0 to 3 but are not simultaneously 0, 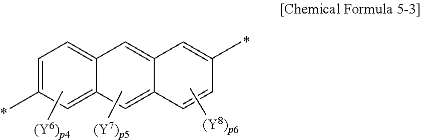
where Y⁶ to Y⁸ are the same as or different to each other and are each hydrogen, a (C1-C10) alkyl group, or a functional group of the following Chemical Formula 6, at least one of Y⁶ to Y⁸ being the functional group of the following Chemical Formula 6, p4 and p6 are integers of 0 to 3, p5 is an integer of 0 to 2, and p4, p5, and p6 are not simultaneously 0, 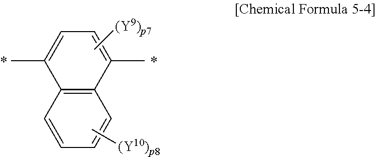
where Y⁹ and Y¹⁰ are the same as or different to each other and are each hydrogen, a (C1-C10) alkyl group, or a functional group of the following Chemical Formula 6, at least one of Y⁹ and Y¹⁰ being the functional group of the following Chemical Formula 6, and p7 and p8 are integers of 0 to 2 but are not simultaneously 0, 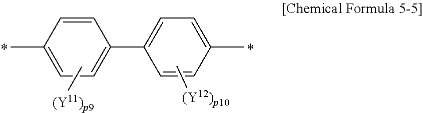
where Y¹¹ and Y¹² are the same as or different to each other and are each hydrogen, a (C1-C10) alkyl group, or a functional group of the following Chemical Formula 6, at least one of Y¹¹ and Y¹² being the functional group of the following Chemical Formula 6, and p9 and p10 are integers of 0 to 4 but are not simultaneously 0, 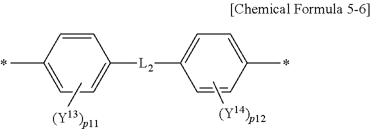
where Y¹³ and Y¹⁴ are the same as or different to each other and are each hydrogen, a (C1-C10) alkyl group, or a functional group of the following Chemical Formula 6, at least one of Y′3 and Y¹⁴ being the functional group of the following Chemical Formula 6, p11 and p12 are integers of 0 to 4, L₂ is an ether group, a sulfide group, a ketone group, an amide group, a sulfoxide group, a sulfone group, an azo group, a cyanide group, a substituted or unsubstituted (C1-C20) alkylene group, a substituted or unsubstituted (C2-C20) alkenylene group, a substituted or unsubstituted (C6-C30) arylene group, a divalent organic functional group substituted or unsubstituted with at least one functional group of the following Chemical Formula 6, or a divalent organic functional group of the following Chemical Formulas 7-1 to 7-3, and in the case in which L₂ is not substituted with the functional group of the following Chemical Formula 6, one of p11 and p12 is not 0, and
in Chemical Formulas 5-1 and 5-6, at least one hydrogen atom of each aromatic ring is substituted with halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, or Z₁ (Z₁ is the same as in Chemical Formula 1).) 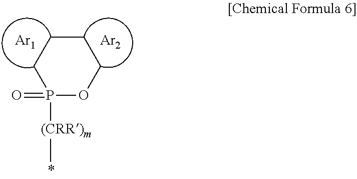
where Ar₁ and Ar₂ are substituted or unsubstituted (C4-C30) aromatic ring groups, R and R′ are the same as or different to each other and are each hydrogen, a (C1-C20) alkyl group, or a (C6-C30) aryl group, and m is an integer of 0 to 3, 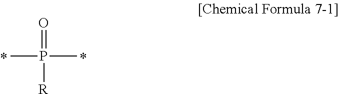
where R is hydrogen, halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, or a substituted or unsubstituted (C6-C30) aryloxy group, 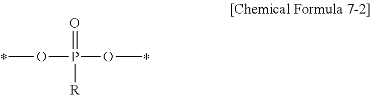
where R is hydrogen, halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, or a substituted or unsubstituted (C6-C30) aryloxy group, 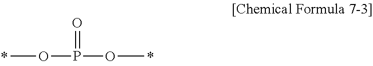
where q is an integer of 2 to 5, and R is each independently hydrogen or one of functional groups represented by the following Chemical Formula 11, 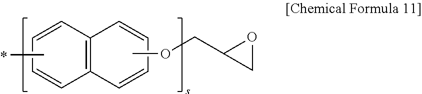
where s is an integer of 1 to 5.

2. The resin composition for a printed circuit board of claim 1, wherein the ether-type naphthalene-based epoxy resin is contained in a content of 30 to 70 wt %.

3. The resin composition for a printed circuit board of claim 1, wherein the ether-type naphthalene-based epoxy resin is a mixture of ether-type naphthalene-based epoxy resins of the following Chemical Formulas 12-1 and 12-2:

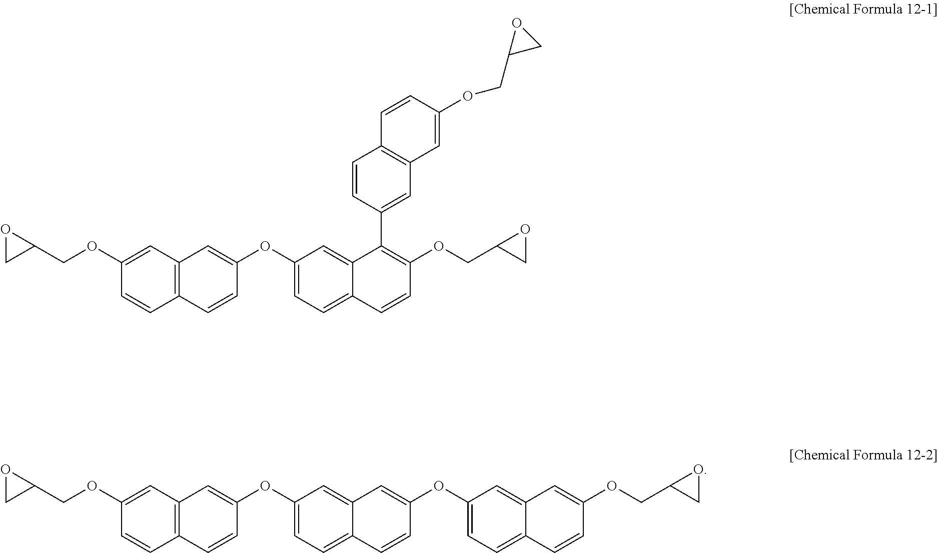 [SMILES: c1cc2ccc(Oc3ccc4ccc(OCC5CO5)c(-c5ccc6ccc(OCC7CO7)cc6c5)c4c3)cc2cc1OCC1CO1 ; c1cc2ccc(Oc3ccc4ccc(Oc5ccc6ccc(OCC7CO7)cc6c5)cc4c3)cc2cc1OCC1CO1]

4. The resin composition for a printed circuit board of claim 3, wherein a mixing weight ratio of the ether-type naphthalene-based epoxy resins of Chemical Formulas 12-1 and 12-2 is 5:5 to 6:4.

5. The resin composition for a printed circuit board of claim 1, wherein the liquid crystal oligomer has a number average molecular weight of 3,500 to 5,000 g/mol.

6. The resin composition for a printed circuit board of claim 1, wherein the structural unit of Chemical Formula 1 is included in a content of 5 to 60 mol % based on a total amount of the liquid crystal oligomer, and the structural unit of Chemical Formula 2 is included in a content of 40 to 95 mol % based on the total amount of the liquid crystal oligomer.

7. The resin composition for a printed circuit board of claim 1, wherein in Chemical Formula 4-7, L₁ is an ether group, a sulfide group, a ketone group, a sulfoxide group, a sulfone group, an azo group, a cyanide group, a substituted or unsubstituted (C1-C20) alkylene group, a substituted or unsubstituted (C1-C20) alkenylene group, or a substituted or unsubstituted (C6-C30) arylene group.

8. The resin composition for a printed circuit board of claim 1, wherein in Chemical Formula 5-6, L₂ is an ether group, a sulfide group, a ketone group, an amide group, a sulfoxide group, a sulfone group, an azo group, a cyanide group, a substituted or unsubstituted (C1-C20) alkylene group, a substituted or unsubstituted (C2-C20) alkenylene group, a substituted or unsubstituted (C6-C30) arylene group, a divalent organic functional group substituted or unsubstituted with at least one functional group of Chemical Formula 6, or a divalent organic functional group of Chemical Formulas 7-1 to 7-3.

9. The resin composition for a printed circuit board of claim 1, wherein the Chemical Formula 6 is represented by the following Chemical Formula 9, 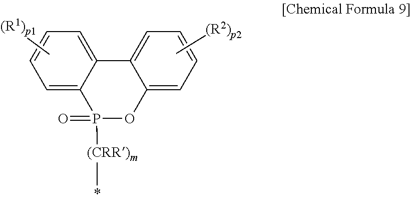
where R¹ and R² are the same as or different to each other and are each hydrogen, halogen, a substituted or unsubstituted (C1-C20) alkyl group, a substituted or unsubstituted (C1-C20) alkoxy group, a substituted or unsubstituted (C3-C20) cycloalkyl group, a substituted or unsubstituted (C6-C30) aryl group, a substituted or unsubstituted (C7-C30) arylalkyl group, a substituted or unsubstituted (C6-C30) aryloxy group, or Z₁ (Z₁ is the same as in Chemical Formula 1), p1 and p2 are integers of 0 to 4, R and R′ are the same as or different to each other and are each hydrogen, a (C1-C20) alkyl group, or a (C6-C30) aryl group, and m is an integer of 0 to 3.

10. The resin composition for a printed circuit board of claim 1, wherein the liquid crystal oligomer is represented by the following Chemical Formula 10. 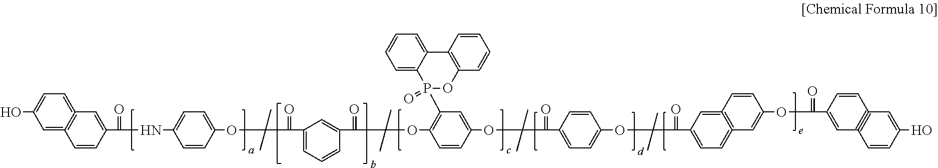
where a, b, c, d, and e refer to molar ratios of structural units and are determined in a number average molecular weight of the liquid crystal oligomer.

11. The resin composition for a printed circuit board of claim 1, further comprising a maleimide-based resin.

12. The resin composition for a printed circuit board of claim 11, wherein the maleimide-based resin is represented by the following Chemical Formula 13, 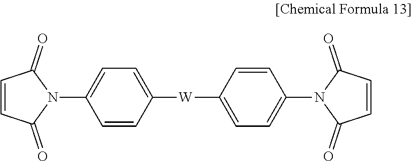
where W is a single bond, an ether group, a sulfide group, a ketone group, a sulfoxide group, a sulfone group, a substituted or unsubstituted (C1-C20) alkylene group, a substituted or unsubstituted (C2-C20) alkoxylene group, a substituted or unsubstituted (C6-C30) arylene group, or a substituted or unsubstituted (C6-C30) (hetero)arylene group including at least one of an ether group, a sulfide group, a ketone group, a sulfoxide group, a sulfone group, an amide group, and an ester group.

13. A copper clad laminate comprising:
an insulating layer containing the resin composition of claim 1; and
a copper foil formed on at least one of upper and lower surfaces.

14. The copper clad laminate of claim 13, wherein the insulating layer further contains a reinforcing material.

15. A printed circuit board comprising:
an insulating layer containing the resin composition of claim 1; and
a circuit pattern formed on the insulating layer.

16. The printed circuit board of claim 15, wherein the insulating layer further contains a reinforcing material.
